(19) United States
(12) Patent Application Publication
(10) Pub. No.: US 2005/0111186 A1
(43) Pub. Date: May 26, 2005

(54) [FAN MODULE]

(76) Inventor: ING-JER CHIOU, TAIPEI CITY (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/708,017

(22) Filed: Feb. 3, 2004

(30) Foreign Application Priority Data
Nov. 21, 2003 (TW) 92132668

(51) Int. Cl. H05K 7/20

(52) U.S. Cl. 361/695

(57) ABSTRACT

A fan module suitable for mounting on a portable electronic device is provided. The fan module has a housing, a fan and a screen. The housing at least has a mounting space, an air inlet and an air outlet. The mounting space connects the air inlet to the air outlet. The fan is installed inside mounting space and the screen is set on the housing covering the air inlet. The screen has a plurality of meshes. The pitch between the centers of any two adjacent meshes is at most 2 mm. Hence, the screen-covered air inlet can prevent small conductive objects from entering the portable electronic device to cause operational failure.

### BACKGROUND OF INVENTION

1. Field of the Invention

The present invention relates to a fan module. More particularly, the present invention relates to a screen mounted fan module suitable for mounting on a portable electronic device such that the screen is able to prevent small conductive objects from entering the portable electronic device.

2. Description of the Related Art

As the level of integration of circuits inside an integrated circuit (IC) chip increases, the amount of heat produced by an IC chip also increases proportionately. When a personal computer system is in operation, the highly integrated IC chips (for example, the central processor or graphic chip) inside the system produces a lot of heat. To prevent any drop in the operating efficiency or damages to the IC chip due to long periods of operation, the IC chip must be maintained at a constant operating temperature. With the rapid increase in computational speed, the demand for a highly efficient cooling system is even more important. Hence, aside from attaching a heat sink directly on the surface of electronic devices to increase heat-dissipating area, an air current blowing from a cooling fan is an additional means of dumping the heat from the heat sink to the atmosphere.

With intense research on portable electronic devices in recent years, many types of high-speed, high-efficiency, light-weight and compact portable electronic devices are produced. The most common portable electronic devices include notebook computers, cellular phones, personal digital assistants (PDA), palmtop computers and tablet computers. Among various portable electronic devices, notebook computers generally have the greatest demand for cooling. However, the limited space inside a notebook computer renders the installation of a highly efficient cooling system difficult. In general, a fan module is installed inside a notebook computer so that hot air is carried away from the interior to cool down the computer.

FIG. 1 is a perspective view of a conventional fan module. As shown in FIG. 1, the fan module 100 is suitable for mounting inside a notebook computer. The fan module 100 comprises a housing 110 and a fan 120. The housing 110 has a mounting space 112, an air inlet 114 and an air outlet 116. The mounting space 112 connects the air inlet 114 to the air outlet 116. The fan 120 is set inside the mounting space 112 in such a way that the air inlet 114 exposes the fan 120. When the fan module 100 is in operation, hot air inside the notebook computer is sucked into the mounting space 112 through the air inlet 114 and then blown out of the notebook computer through the air outlet 116. With the heat inside the notebook computer constantly carried away by the fan 120, a desirable ambient temperature can be maintained.

It should be noted that small external conductive objects (for example, pin clips or staple pins) can easily enter into the interior of the notebook computer through the fan module as shown in FIG. 1, for example, in a working environment. Because the interior of the notebook computer has a lot of electrical contacts or circuits, the notebook computer may malfunction or sustain some damage when the small conductive object manages to contact these electrical contacts or circuits by accident.

To prevent any small conductive objects from getting inside the notebook computer through the fan module, a screen with a large number of meshes is often mounted on the air outlet of the fan module. At present, the safety specification stipulates that the maximum pitch between adjacent meshes in a screen must not be greater than 2 mm. Since the screen mounted on the air outlet may actually bump into other external objects, the screen must have sufficient strength to withstand such impacts without major damages. Hence, the safety specification of most portable electronic device also stipulates that the threads constituting the screen must have a diameter at least 0.45 mm. However, with an increase in the diameter of the threads forming the screen, percentage opening in the screen is reduced leading to drop in the convection efficiency of the airflow produced by the fan module for cooling the notebook computer.

### SUMMARY OF INVENTION

Accordingly, at least one objective of the present invention is to provide a fan module for exhausting heat from the interior of a portable electronic device to the exterior. The fan module further has a screen mounted on an air inlet of the fan for preventing small conductive objects from getting into the interior of the portable electronic device.

To achieve these and other advantages and in accordance with the purpose of the invention, as embodied and broadly described herein, the invention provides a fan module for a portable electronic device. The fan module comprises a housing, a fan and a screen. The housing has at least a mounting space, an air inlet and an air outlet. The mounting space connects the air inlet to the air outlet. The fan is installed inside mounting space and the screen is set on the housing covering the air inlet. The screen has a plurality of meshes. The pitch between the centers of any two adjacent meshes is at most 2 mm.

According to the fan module of the embodiment of present invention, the rotation axis of the fan is parallel to the central axis of the air inlet of the housing but the central axis of the air inlet is perpendicular to the central axis of the air outlet.

According to the fan module of the embodiment of present invention, the screen is fabricated using either a metallic or a plastic material.

In brief, the fan module of the present invention is suitable for cooling the interior of a portable electronic device. The fan module has a screen with a plurality of meshes such that the pitch of the adjacent meshes is at most 2 mm. With the screen mounted over the air inlet, small conductive objects are prevented from getting into the interior of the portable electronic device through the air outlet and then the air inlet of the housing. Thus, related safety specifications of a portable electronic device are met.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a perspective view of a conventional fan module.

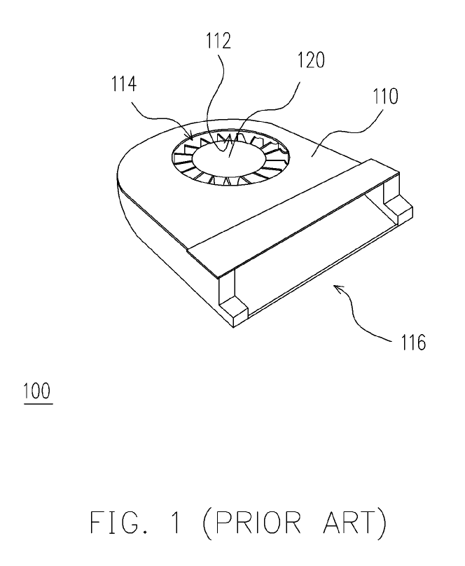

FIG. 2A is a perspective view showing all the separate components of a fan module according to one preferred embodiment of this invention.

FIG. 2B is a perspective view showing all separate components assembled together to form a fan module according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

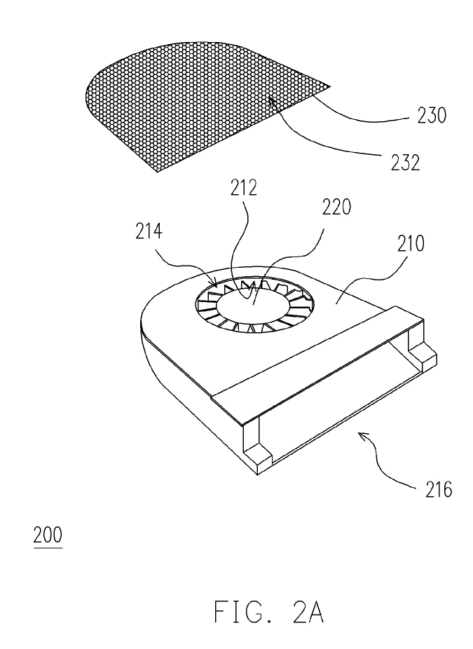

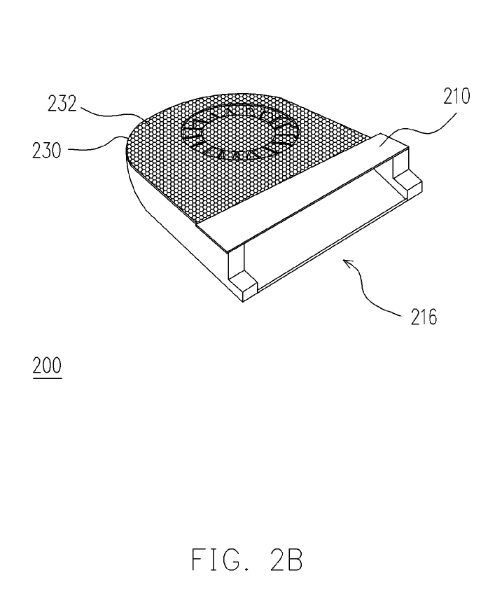

FIG. 2A is a perspective view showing the components of a fan module according to one preferred embodiment of this invention. A fan module 200 suitable for cooling a portable electronic device such as a notebook computer is shown in FIG. 2A. The fan module 200 comprises a housing 210, a fan 220 and a screen 230. The housing 210 has a mounting space 212, an air inlet 214 and an air outlet 216. The mounting space 212 connects the air inlet 214 to the air outlet 216. The air outlet 216 is exposed on the exterior of the portable electronic device and the air inlet 214 is located in the interior of the portable electronic device.

The fan 220 is set within the mounting space 212 of the housing 210. The upper section of the fan 220 is exposed through the air inlet 214 over the housing 210. Thus, when the fan 220 rotates, hot air inside the portable electronic device is sucked into the mounting space 212 through the air inlet 214 and then exhausted to the atmosphere through the air outlet 216. It should be noted that the rotation axis of the fan 220 is parallel to the central axis of the air inlet 214 but the rotation axis of the fan 220 is perpendicular to the central axis of the air outlet 216.

FIG. 2B is a perspective view showing the components assembled together to form a fan module according to one preferred embodiment of this invention. As shown in FIGS. 2A and 2B, the screen 230 is set on the housing 210 covering the air inlet 214 so that small conductive objects are prevented from getting into the portable electronic device via the air outlet 214, the mounting space 212 and the air inlet 214. The screen 230 has a plurality of meshes 232. The screen 230 is fastened to the housing 210 by means of glue or mechanical locks. To increase the heat dissipating capacity of the fan module 200, the screen 230 can be fabricated using a metallic material. However, to lower overall production cost, the screen 230 can be fabricated using a plastic material.

When the notebook computer with a fan module designed according to the present invention is carried around, any small external conductive objects (for example, pin clips or staple pins) that happen to get through the air outlet and the mounting space are blocked by the screen on the air inlet. Thus, the small conductive objects is prevented from reaching any electrical contacts or circuits inside the portable electronic device to cause any failure or major damages by accident.

Furthermore, the screen is set on the housing within the portable electric device. Hence, the screen will not come in direct contact with any external objects. Although the safety specifications of a portable electronic device demands the pitch between the centers of two adjacent meshes in the screen must be 2 mm or less, the diameter of the threads constituting the screen need not be greater than 0.45 mm. In other words, the percentage opening in the screen is higher so that the convection efficiency of the fan module is increased.

In summary, major advantages of the fan module according to the present invention includes: 1. The screen of the fan module is set on the housing over the air inlet so that small conductive objects are prevented from getting into the interior of the portable electronic device by way of the air outlet, the mounting space and the air inlet. Hence, failure or damage resulting from a direct contact of these objects with bare circuits or contacts inside the portable electronic device is minimized. 2. The screen can be directly bonded on the housing to simplify the production process. Consequently, the manufacturing cost of the fan module is reduced. 3. The opening percentage of the screen in the fan module is larger than a conventional fan module. Therefore, the fan module of the present invention has a higher convection efficiency.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A fan module for a portable electronic device, comprising:
a housing having at least a mounting space, an air inlet and an air outlet, wherein the mounting space connects the air inlet to the air outlet;
a fan set within the mounting space; and
a screen set on the housing covering the air inlet, wherein the screen has a plurality of meshes such that the pitch between adjacent meshes is smaller than or equal to 2 mm.

2. The fan module of claim 1, wherein the rotation axis of the fan is parallel to the central axis of the air inlet of the housing but the central axis of the air inlet is perpendicular to the central axis of the air outlet.

3. The fan module of claim 1, wherein material constituting the screen is selected from a group consisting of metal and plastic.

4. The fan module of claim 1, wherein the fan is exposed through the air inlet.
